(19) United States
(12) Patent Application Publication
(10) Pub. No.: US 2026/0184991 A1
(43) Pub. Date: Jul. 2, 2026

(54) ETCHANT COMPOSITION, METHOD OF PATTERNING METAL LAYER AND METHOD OF PRODUCING ELECTRONIC DEVICE USING THE SAME

(71) Applicants: Samsung Display Co., Ltd., Yongin-si (KR); DONGWOO FINE-CHEM Co., Ltd., Iksan-si (KR)

(72) Inventors: Shinhyuk Yang, Yongin-si (KR); Hanhee Yoon, Yongin-si (KR); Beomsoo Kim, Iksan-si (KR); Donghan Kang, Yongin-si (KR); Youngjin Yoon, Iksan-si (KR); Eunwon Lee, Iksan-si (KR); Hyeonsu Cho, Iksan-si (KR); Suckjun Lee, Iksan-si (KR)

(21) Appl. No.: 19/436,686

(22) Filed: Dec. 30, 2025

(30) Foreign Application Priority Data
Dec. 31, 2024 (KR) 10-2024-0202692

(51) Int. Cl. C09K 13/08; G03F 7/00; H10H 29/01; H10P 50/00

(52) U.S. Cl. CPC C09K 13/08; G03F 7/0007; H10H 29/011; H10P 50/71

(57) ABSTRACT

Provided is an etchant composition including, about 3.0 wt % to about 15.0 wt % of ammonium persulfate, about 0.1 wt % to about 5.0 wt % of an inorganic acid, about 0.1 wt % to about 2.0 wt % of a fluorine-containing ammonium salt, about 0.01 wt % to about 1.5 wt % of a chlorine-containing ammonium salt, about 0.1 wt % to about 2.0 wt % of a 2-nitrogen cyclic compound, about 0.1 wt % to about 2.0 wt % of a 4-nitrogen cyclic compound, about 0.1 wt % to about 3.0 wt % of an aminosulfonic acid, and a remainder of water such that the total weight of the entire etchant composition becomes 100 wt %, wherein the weight ratio of the 4-nitrogen cyclic compound to the 2-nitrogen cyclic compound is in a range of about 1.6 to about 5.0.

### CROSS-REFERENCE TO RELATED APPLICATION

The present application claims priority to and the benefit of Korean Patent Application No. 10-2024-0202692, filed on Dec. 31, 2024, in the Korean Intellectual Property Office, the entire content of which is hereby incorporated by reference.

### BACKGROUND

### 1. Field

One or more embodiments of the present disclosure relate to an etchant composition, and a method of patterning a metal layer and a method of producing an electronic device, which uses the etchant composition.

### 2. Description of the Related Art

As the field of displays which express a variety of electrical signal information develops, various display devices having excellent characteristics such as thinness, light weight, and low power consumption are being researched and developed.

As the resolution of display devices increases, control of the etching profiles of the various wirings and electrodes included in the display device is becoming more important.

### SUMMARY

One or more embodiments of the present disclosure include an etchant composition capable of etching a multi-layer film, a method of patterning a metal layer, a method of producing a display device using the same, and a method of producing an electronic device using the same.

Additional aspects of embodiments will be set forth in part in the description which follows and, in part, will be apparent from the description, or may be learned by practice of the presented embodiments of the disclosure.

According to one or more embodiments, provided is an etchant composition, including:
about 3.0 wt % to about 15.0 wt % of ammonium persulfate;
about 0.1 wt % to about 5.0 wt % of an inorganic acid;
about 0.1 wt % to about 2.0 wt % of a fluorine-containing ammonium salt;
about 0.01 wt % to about 1.5 wt % of a chlorine-containing ammonium salt;
about 0.1 wt % to about 2.0 wt % of a 2-nitrogen cyclic compound (e.g., a cyclic compound including 2 nitrogen atoms in a ring thereof);
about 0.1 wt % to about 2.0 wt % of a 4-nitrogen cyclic compound (e.g., a cyclic compound including 4 nitrogen atoms in a ring thereof);
about 0.1 wt % to about 3.0 wt % of an aminosulfonic acid; and
the remainder water, to bring the total weight of the etchant composition to 100 wt %,
wherein the weight ratio of the 4-nitrogen cyclic compound to the 2-nitrogen cyclic compound is in a range of about 1.6 to about 5.0.

The inorganic acid may include nitric acid (HNO₃), sulfuric acid (H₂SO₄), p-toluenesulfonic acid (CH₃C₆H₄SO₃), chloric acid (HClO₃), or a suitable combination thereof.

The inorganic acid may be nitric acid.

The fluorine-containing ammonium salt may include ammonium bifluoride.

The 2-nitrogen cyclic compound may include imidazole, benzimidazole, pyrazole, indazole, pyridazine, pyrimidine, pyrazine, or any suitable combination thereof.

In an embodiment, the 2-nitrogen cyclic compound may be imidazole.

The aminosulfonic acid may include, for example, sulfamic acid, taurine, cysteic acid, homocysteic acid, aminomethanesulfonic acid, 3-amino-1-propanesulfonic acid, or any suitable combination thereof.

The 4-nitrogen azole compound may include 5-aminotetrazole, 5-methyltetrazole, 1-methyl-5-aminotetrazole, 1-ethyl-5-aminotetrazole, 5-mercapto-1-methyltetrazole, 5-methoxy-1H-tetrazole, 1H-tetrazole, or any suitable combination thereof.

In an embodiment, the 4-nitrogen azole compound may be 5-aminotetrazole.

The corrosion inhibitor may include the 4-nitrogen azole compound.

The etchant composition may be to etch a metal film, a metal oxide film, a metal nitride film, or a suitable combination thereof.

According to another aspect of embodiments,
provided is a method of patterning a metal layer, the method including: providing a substrate;
forming a metal layer on the substrate;
forming a photoresist pattern on the metal layer; and
etching the metal layer using the above-described etchant composition to pattern the metal layer.

The metal layer may be a multi-layer.

The metal layer may include or consist of a metal, a metal oxide, a metal nitride, or a suitable combination thereof.

In an embodiment, the metal may include copper, titanium, a titanium alloy, or any suitable combination thereof,
and the titanium alloy may include titanium; and molybdenum (Mo), tantalum (Ta), chromium (Cr), nickel (Ni), neodymium (Nd), or any suitable combination thereof.

The metal oxide may include an oxide of indium (In), tin (Sn), gallium (Ga), zinc (Zn), or any suitable combination thereof.

The metal oxide may be indium tin oxide.

The metal nitride may include titanium nitride, tantalum nitride, or a suitable combination thereof.

In an embodiment, the metal layer may include a first metal layer and a second metal layer,
wherein the first metal layer may include titanium and/or a titanium alloy,
the titanium alloy may include titanium; and molybdenum (Mo), tantalum (Ta), chromium (Cr), nickel (Ni), neodymium (Nd), or any suitable combination thereof,
and the second metal layer may include copper.

In an embodiment, the metal layer may further include a metal oxide layer on the second metal layer, and the metal oxide layer may include indium tin oxide.

According to another aspect of embodiments,
provided is a method of producing a display device or an electronic device, including a thin-film transistor including a semiconductor layer, a gate electrode, and source/drain electrodes; and a light-emitting element electrically connected to the source/drain electrodes, wherein the method of producing the display device includes:
providing a substrate;
forming a metal layer on the substrate;
forming a photoresist pattern on the metal layer; and
etching the metal layer using the above-described etchant composition to form a metal layer pattern,
wherein the metal layer pattern may constitute the gate electrode and/or the source/drain electrodes.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a plan view schematically illustrating a display device according to an embodiment;

FIG. 2 is a cross-sectional view schematically illustrating a portion of the display device of FIG. 1;

FIG. 3 is a schematic diagram illustrating a method of measuring side etching;

FIG. 4 is a pair of cross-sectional scanning electron microscope (SEM) images of a specimen etched using an etchant composition of Example 3; and

FIG. 5 is a cross-sectional SEM image of a specimen etched using an etchant composition of Comparative Example 5.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, embodiments are merely described below, by referring to the drawings, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Because the subject matter of the disclosure may be modified in various suitable ways and may have many embodiments, example embodiments will be illustrated in the drawings and described in more detail in the detailed description. The effects and features of embodiments of the disclosure, and methods of achieving them, will become clear with reference to the embodiments described below in detail together with the drawings. However, the subject matter of the disclosure is not limited to the embodiments described herein and may be implemented in various suitable forms.

In the following embodiments, the terms first, second, and/or the like are not intended to be limiting, however are used to distinguish one component from another component.

In the following embodiments, the singular expression includes the plural unless the context clearly indicates otherwise.

In the following embodiments, the terms including, has, and/or the like are intended to imply the presence of the recited features or components and do not preclude the possibility of the addition of one or more other features or components.

In the following embodiments, when a portion of a film, area, component, and/or the like is said to be over or on the upper portion of another portion, this includes not only when it is directly on the upper portion of another portion, however also when there are other films, areas, components, and/or the like therebetween.

In the drawings, components may be exaggerated or reduced in size for ease of illustration. For example, the size and thickness of each configuration shown in the drawings may be arbitrary for ease of description and the disclosure is not necessarily limited to those shown.

### Etchant Composition

According to one or more embodiments, provided is an etchant composition, including:
about 3.0 wt % to about 15.0 wt % of ammonium persulfate;
about 0.1 wt % to about 5.0 wt % of an inorganic acid;
about 0.1 wt % to about 2.0 wt % of a fluorine-containing ammonium salt;
about 0.01 wt % to about 1.5 wt % of a chlorine-containing ammonium salt;
about 0.1 wt % to about 2.0 wt % of a 2-nitrogen cyclic compound (e.g., a cyclic compound including 2 nitrogen atoms in a ring thereof);
about 0.1 wt % to about 2.0 wt % of a 4-nitrogen cyclic compound (e.g., a cyclic compound including 4 nitrogen atoms in a ring thereof);
about 0.1 wt % to about 3.0 wt % of an aminosulfonic acid; and
the residual water (e.g., the remainder water), to bring the total weight of the etchant composition to 100 wt %,
wherein the weight ratio of the 4-nitrogen cyclic compound to the 2-nitrogen cyclic compound is in a range of about 1.6 to about 5.0.

The wt % of the above components represent values relative to the total weight of the etchant composition.

The ammonium persulfate may be the main oxidizing agent for copper, for example, the main component of copper etching, and may control the etching rate. The ammonium persulfate may oxidize copper into copper ions (Cu²⁺) to enable etching.

An amount of the ammonium persulfate may be about 3.0 wt % to about 15.0 wt % based on the total 100 wt % of the etchant composition. If the ammonium persulfate is included at less than 3.0 wt %, etching may not occur or the etching rate may decrease. If the ammonium persulfate is included at more than 15.0 wt %, it may be difficult to control the etching rate and the anions may increase excessively, which may lower the etching uniformity of the multi-layer film.

The inorganic acid may be an auxiliary oxidizing agent utilized to etch. The inorganic acid may include nitric acid (HNO₃), sulfuric acid (H₂SO₄), phosphoric acid (H₃PO₄), phosphorous acid (H₃PO₃), p-toluenesulfonic acid (CH₃C₆H₄SO₃), chloric acid (HClO₃) or a suitable combination thereof. In an embodiment, the inorganic acid may be nitric acid.

An amount of the inorganic acid may be about 0.1 wt % to about 5.0 wt % based on the total 100 wt % of the etchant composition. If the inorganic acid is included at less than 0.1 wt %, the etching rate may decrease, residue may occur and/or defects may occur in the etching profile. If the inorganic acid is included at more than 5.0 wt %, over-etching may occur and/or cracks may occur in the photoresist, thereby reducing productivity.

The fluorine-containing ammonium salt may serve a role in dissociating a metal oxide oxidized by an oxidizing agent. For example, it may act as a dissociating agent for titanium (Ti). The fluorine-containing ammonium salt may also have the ability to etch indium oxide and may serve as an etchant for indium oxide, and may remove residues and/or tips that may occur during etching. In an embodiment, the fluorine-containing ammonium salt may be ammonium bifluoride.

The fluorine-containing ammonium salt may be about 0.1 wt % to about 2.0 wt % based on the total 100 wt % of the etchant composition. In another example, the fluorine-containing ammonium salt may be about 0.6 wt % to about 1.0 wt %. If the fluorine-containing ammonium salt is included at less than 0.1 wt %, the etching rate may decrease, and residue and/or tip formation may occur. If the fluorine-containing ammonium salt is included at more than 2.0 wt %, it may damage the lower layer of the substrate, for example, a substrate forming a base of a wiring substrate including wiring, and/or a silicon-based insulation layer (e.g., a silicon-based electrical insulation layer).

The chlorine-containing ammonium salt may improve yield by preventing or reducing over-etching of a metal. The chloride ion of the chlorine-containing ammonium salt may have an effect of controlling corrosion between the photoresist and the metal pattern. A chloride ion may bind to the metal on the surface of the metal pattern in the gap between the photoresist and the metal pattern, preventing or reducing penetration of the oxidizing agent in the etchant composition into the gap and excessively causing side etching on the upper portion of the metal pattern. In an embodiment, the chlorine-containing ammonium salt may be ammonium chloride.

An amount of the chlorine-containing ammonium salt may be about 0.01 wt % to about 1.5 wt % based on the total 100 wt % of the etchant composition. In another example, the amount of the chlorine-containing ammonium salt may be about 0.1 wt % to about 1.5 wt % or about 1.0 wt % to about 1.3 wt %.

The 2-nitrogen cyclic compound may stabilize the variation in the side etching rate according to the number of substrates processed with the etchant composition. As the number of substrates processed with the etchant composition increases, the concentration of copper ions (Cu²⁺) in the etchant composition increases. Initially, while the concentration of copper ions (Cu²⁺) in the etchant composition increases to a set or certain value, the side etching rate increases together as the substrates are processed, and when the concentration of copper ions (Cu²⁺) increases beyond the set or certain value, the side etching rate decreases as the substrates are processed. The above described initial increasing of side etching rate is referred to as side etch hunting. The 2-nitrogen cyclic compound is coordinated to copper ions (Cu2+) initially generated in the etchant composition, alleviating the phenomenon of initial increase in side etching, and reducing the variation in side etching rate according to the number of substrates processed, thereby ensuring process stability. In an embodiment, the 2-nitrogen cyclic compound may include imidazole, benzimidazole, pyrazole, indazole, pyridazine, pyrimidine, pyrazine, or any suitable combination thereof. In an embodiment, the 2-nitrogen cyclic compound may be imidazole.

An amount of the 2-nitrogen cyclic compound may be about 0.1 wt % to about 2.0 wt % based on the total 100 wt % of the etchant composition. If the 2-nitrogen cyclic compound is included at less than 0.1 wt %, a side etching hunting phenomenon may occur. If the 2-nitrogen cyclic compound is included at more than 2.0 wt %, the etching rate may decrease, thereby reducing the etching efficiency.

The aminosulfonic acid may function as a buffer against changes in acidity in the etchant composition according to the number of substrates processed. The aminosulfonic acid may prevent or reduce variations in the taper angle of the copper pattern according to the number of substrates processed with the etchant composition. In an embodiment, the aminosulfonic acid may include, for example, sulfamic acid, taurine, cysteic acid, homocysteic acid, aminomethanesulfonic acid, 3-amino-1-propanesulfonic acid or any suitable combination thereof. In an embodiment, the aminosulfonic acid may be sulfamic acid.

The aminosulfonic acid may be included at about 0.1 wt % to about 3.0 wt % based on the total 100 wt % of the etchant composition. If the aminosulfonic acid is included at less than 0.1 wt %, the variation in the taper angle may increase as the cumulative number of processed substrates increases. If the aminosulfonic acid is included at more than 3.0 wt %, the etching rate may decrease, thereby reducing the etching efficiency.

The 4-nitrogen cyclic compound may serve as a corrosion inhibitor that prevents or reduces corrosion of copper.

The 4-nitrogen cyclic compound may include, for example, 5-aminotetrazole, 5-methyltetrazole, 1-methyl-5-aminotetrazole, 1-ethyl-5-aminotetrazole, 5-mercapto-1-methyltetrazole, 5-methoxy-1H-tetrazole, 1H-tetrazole, or any suitable combination thereof.

An amount of the 4-nitrogen cyclic compound may be about 0.1 wt % to about 2.0 wt % based on the total 100 wt % of the etchant composition. If the 4-nitrogen cyclic compound is included at less than 0.1 wt %, it may become difficult to control the copper etching rate, leading to over-etching and non-uniform etching. If the 4-nitrogen cyclic compound is included at more than 2.0 wt %, the etching rate may decrease, thereby reducing etching efficiency.

In embodiments, by satisfying the weight ratio of the 4-nitrogen cyclic compound to the 2-nitrogen cyclic compound in a range of about 1.6 to about 5.0, it may be possible to control the etching ratio of the vertical direction to horizontal direction of the wiring, while concurrently (e.g., simultaneously) improving the problem of intensified side etching according to the increase in copper ions in the etchant composition.

Furthermore, the etchant composition of the disclosure may control the etching ratio of the vertical direction to horizontal direction through controlling chelation of copper ions and crevice corrosion of chloride ions. The vertical direction may be the direction corresponding to the height of the wiring, and the horizontal direction may be the direction perpendicular (e.g., substantially perpendicular) to the vertical direction. If the etching ratio in the vertical direction is high, the side angle of the wiring approaches 90 degrees. The side angle of the wiring refers to the angle formed between the side of the wiring and the bottom of the wiring. If the side angle of the wiring is less than 90 degrees, the width of the upper surface of the wiring is narrower than the width of the bottom surface, and if the side angle of the wiring is more than 90 degrees, the width of the upper surface of the wiring is wider than the width of the bottom surface. If the side angle of the wiring is 90 degrees, the width of the bottom surface and upper surface of the wiring is the same. If the side angle of the wiring is vertical, the area of the wiring cross-section is large at the desired scale, therefore the resistance (e.g., electrical resistance) may be reduced, but it may be difficult to perform the subsequent thin-film deposition process that conforms to the wiring. If the side angle of the wiring is low, for example, less than 40 degrees, the wiring cross-section becomes closer to a triangle, which increases resistance (e.g., electrical resistance) and may cause the wiring to break at vulnerable points. Therefore, it is desirable for the wiring to have a suitable or appropriate side angle. Furthermore, the etchant composition of embodiments of the disclosure may improve the etching ratio of the vertical direction to horizontal direction, allowing the wiring to have a side angle of about 50 degrees to about 60 degrees.

In embodiments, a plurality of substrates may be sequentially processed by repeatedly using the etchant composition. A side etch hunting phenomenon may occur in which the rate of side etching increases due to copper ions (Cu²⁺) in the initial substrates processing. The etchant composition according to an embodiment may effectively prevent or reduce variations in side etching and side angle according to the number of substrates processed in the initial substrates processing.

In an embodiment, the etchant composition may be a composition for etching a metal film, a metal oxide film, a metal nitride film, or a suitable combination thereof. In another embodiment, the etchant composition may be a composition for etching a metal film and a metal oxide film.

For example, the etchant composition may etch a multi-layer film including a metal film and a metal oxide film.

For example, the metal film may include copper, titanium, a titanium alloy, or any suitable combination thereof, and the titanium alloy may include titanium; and molybdenum (Mo), tantalum (Ta), chromium (Cr), nickel (Ni), neodymium (Nd) or any suitable combination thereof.

For example, the metal film may include a first metal film and a second metal film, wherein the first metal film may include titanium, and/or a titanium alloy, wherein the titanium alloy includes titanium; and molybdenum (Mo), tantalum (Ta), chromium (Cr), nickel (Ni), neodymium (Nd), or any suitable combination thereof; and the second metal film may include copper.

For example, the metal oxide film may include an oxide of indium (In), tin (Sn), gallium (Ga), zinc (Zn), or any suitable combination thereof. In another example, the metal oxide film may include oxides of In; and Sn, Ga, Zn, or any suitable combination thereof. In another example, the metal oxide film may be an oxide of In and Sn (for example, ITO).

For example, the first metal film may include titanium, the second metal film may include copper, and the metal oxide film may include ITO, but is not limited thereto.

### Metal Layer Patterning

A method of patterning a metal layer using the above-described etchant composition will be further described.

A method of patterning a metal layer according to an embodiment may include:
providing a substrate;
forming a metal layer on the substrate;
forming a photoresist pattern on the metal layer; and
etching the metal layer using the above-described etchant composition. The metal layer may be a single layer or multi-layer. In an embodiment, the metal layer may be a multi-layer. For example, the metal layer may include or consist of a layer consisting of a metal, a layer including or consisting of a metal oxide, a layer including or consisting of a metal nitride, or a suitable combination thereof.

The metal may include copper, titanium, a titanium alloy, or any suitable combination thereof, and the titanium alloy may include titanium; and molybdenum (Mo), tantalum (Ta), chromium (Cr), nickel (Ni), neodymium (Nd), or any suitable combination thereof.

The metal oxide may include an oxide of indium (In), tin (Sn), gallium (Ga), zinc (Zn), or any suitable combination thereof. For example, the metal oxide may be indium tin oxide.

The metal nitride may include titanium nitride, tantalum nitride, or a suitable combination thereof. For example, the metal oxide may be titanium nitride.

In an embodiment, the metal layer may include a first metal layer and a second metal layer. The first metal layer may include titanium and/or a titanium alloy, and the second metal layer may include copper.

In an embodiment, the metal layer may further include a metal oxide layer over the second metal layer. For example, the metal oxide layer may include indium tin oxide.

### Production of Display Device

In an embodiment, a display device may be produced using the etchant composition according to an embodiment.

A display device according to an embodiment may include: a thin-film transistor including a semiconductor layer, a gate electrode, and source/drain electrodes; and a light-emitting element electrically connected to the source/drain electrodes. In an embodiment, the display device may further include a bottom metal layer beneath the semiconductor layer. The bottom metal layer may be connected to the source/drain electrodes. In an embodiment, the light-emitting element may be an organic light-emitting element and/or a quantum dot light-emitting element.

A method of producing a display device according to an embodiment may include:
providing a substrate;
forming a metal layer on the substrate;
forming a photoresist pattern on the metal layer; and
etching the metal layer using the above-described etchant composition to form a metal layer pattern,
wherein the metal layer pattern may constitute a gate electrode, a source/drain electrode, and/or a bottom metal layer of the display device.

The metal layer refers to the metal layer in the method of patterning a metal layer as described above.

### Display Device

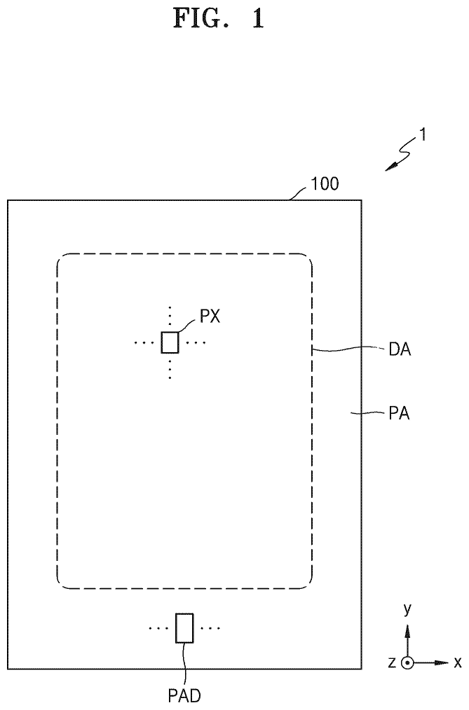

FIG. 1 is a plan view schematically illustrating a display device according to an embodiment.

Referring to FIG. 1, a display device 1 includes a display area DA that displays an image and a peripheral area PA around the display area DA. The display device 1 may provide an image to the outside using light emitted from a display area DA.

In the display area DA, pixels PX provided with various suitable display elements such as an organic light-emitting diode (OLED) may be provided. The pixel PX may be provided in plural, and the plurality of pixels PX may be provided in various suitable forms such as a stripe arrangement, a PENTILE® arrangement structure (e.g., an RGBG matrix, RGBG structure, or RGBG matrix structure), a mosaic arrangement, and/or the like, to implement an image. PENTILE® is a duly registered trademark of Samsung Display Co., Ltd.

If (e.g., when) viewing the display area DA in a plan view, the display area DA may be provided in a rectangular shape as shown in FIG. 1. In another embodiment, the display area DA may be provided in other polygonal shape such as a triangular shape, pentagonal shape, hexagonal shape, or the like, or in a circular shape, an oval shape, an irregular shape, or the like.

The peripheral area PA is an area around the display area DA and may be an area where no image is displayed. The peripheral area PA may fully or partially surround the display area DA. The peripheral area PA may contain various suitable wirings that transmit electrical signals to be applied to the display area DA, and a pad portion PAD to which a printed circuit board and/or driver IC chip may be attached.

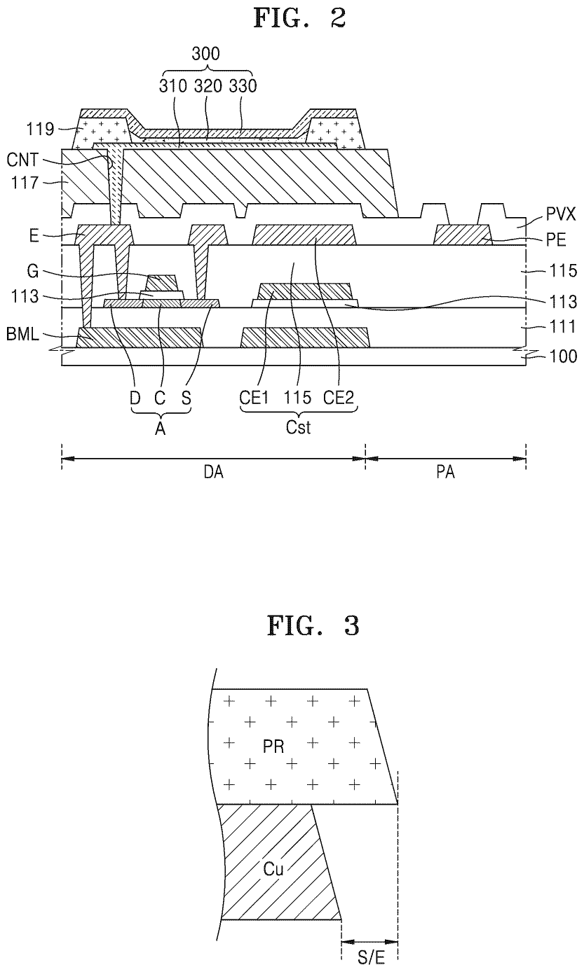

FIG. 2 is a cross-sectional view schematically illustrating a portion of the display device of FIG. 1.

Referring to FIGS. 1 and 2, a display device according to an embodiment includes a thin-film transistor (TFT) on a substrate 100 corresponding to the display area DA and a pad portion PAD on the substrate 100 corresponding to a peripheral area PA.

The display device 1 includes a planarization layer 117 as an insulation layer (e.g., an electrical insulation layer) that exposes a pad portion PAD and disposed on a thin-film transistor (TFT), and includes a pixel definition film 119 on the planarization layer 117.

The substrate 100 may include or consist of various suitable materials such as glass, metal, plastic (e.g., polymer), and/or the like. In an embodiment, the substrate 100 may include a flexible material. In embodiments, flexible material refers to a material that may be easily bent, curved, folded, and/or rolled. The substrate 100 made of the flexible material may include or consist of ultra-thin glass, metal, and/or plastic (e.g., polymer).

The buffer layer 111 may reduce or block the infiltration of foreign substances, moisture, and/or foreign air from a lower portion of the substrate 100, and may provide a flat surface on the substrate 100. The buffer layer 111 may include an inorganic material, such as an oxide and/or nitride, and/or an organic material, and/or an organic-inorganic composite material, and may include a single-layer or multi-layer structure of inorganic material and/or organic material.

A barrier layer may be further included between the substrate 100 and the buffer layer 111. The barrier layer may serve a role in preventing, minimizing, or reducing the penetration of impurities from the substrate 100, and/or the like, into a semiconductor layer A. The barrier layer may include an inorganic material, such as an oxide and/or nitride, and/or an organic material, and/or an organic-inorganic composite, and may include a single-layer or multi-layer structure of inorganic material and/or organic material.

A semiconductor layer A may be on the buffer layer 111. In an embodiment, the semiconductor layer A may include an oxide semiconductor material. The semiconductor layer A may include, for example, at least one oxide of a material selected from the group consisting of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn).

For example, the semiconductor layer A may be an ITZO (InSnZnO) semiconductor layer, an IGZO (InGaZnO) semiconductor layer, and/or the like. Because oxide semiconductor materials have a wide band gap (about 3.1 eV), high carrier mobility, and low leakage current, there is an advantage in that even if the driving time is long, the voltage drop is not large, and the luminance change due to the voltage drop is not large even when driving at low frequencies.

The semiconductor layer A may include a channel area C, and a source area S and a drain area D on one side and the other side of the channel area C, respectively. The semiconductor layer A may include or consist of a single-layer or multi-layer structure.

A bottom metal layer BML may be between the substrate 100 and the buffer layer 111. The bottom metal layer BML may overlap the channel area C of the semiconductor layer A. The bottom metal layer BML may include a conductive material (e.g., an electrically conductive material) including copper (Cu), titanium (Ti), molybdenum (Mo), aluminum (Al), and/or the like, and may be formed as a multi-layer or single layer including the above materials. In an embodiment, the bottom metal layer BML may be formed of a bilayer structure of Ti/Cu.

The bottom metal layer BML may overlap with the semiconductor layer A including an oxide semiconductor material. Because the semiconductor layer A including the oxide semiconductor material has a characteristic of being vulnerable to light, the bottom metal layer BML may prevent or reduce a change of the device characteristics of the thin-film transistor TFT including the oxide semiconductor material due to photocurrent being induced in the semiconductor layer A by external light incident from the substrate 100 side. In an embodiment, the bottom metal layer BML may be connected to the drain area D or the source area S.

A gate insulation layer 113 may be on the semiconductor layer A. The gate insulation layer 113 may include silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnO_{X}, which may be ZnO and/or ZnO₂), and/or the like. The gate insulation layer 113 may be patterned to overlap at least a portion of the semiconductor layer A. For example, the gate insulation layer 113 may be patterned to expose the source area S and the drain area D.

The area where the gate insulation layer 113 and the semiconductor layer A overlap may be understood as the channel area C. The source area S and the drain area D undergo a conductive process through plasma treatment, and/or the like, during which the portion of the semiconductor layer A that overlaps the gate insulation layer 113 (for example, the channel area C) has different properties from the source area S and the drain area D.

In another embodiment, the gate insulation layer 113 may not be patterned to overlap a portion of the semiconductor layer A, but may be on the entire surface of the substrate 100 to cover the semiconductor layer A. A gate electrode G may be over the gate insulation layer 113 to at least partially overlap the semiconductor layer A. In embodiments, a first electrode CE1 of a storage capacitor Cst may be on the gate insulation layer 113. The gate electrode G and the first electrode CE1 of the storage capacitor Cst may be formed as a single layer or a multi-layer including or consisting of copper (Cu), titanium (Ti), molybdenum (Mo), aluminum (Al), platinum (Pt), palladium (Pd), silver (Ag), magnesium (Mg), gold (Au), nickel (Ni), neodymium (Nd), iridium (Ir), chromium (Cr), molybdenum (Mo), tungsten (W), or a suitable combination thereof. In an embodiment, the storage capacitor Cst may include a first electrode CE1 and a second electrode CE2.

An interlayer insulation layer 115 may be provided to cover the semiconductor layer A, the gate electrode G, and the first electrode CE1 of the storage capacitor Cst. The interlayer insulation layer 115 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), zinc oxide (ZnO₂), and/or the like.

An electrode layer E, a second electrode CE2 of a storage capacitor Cst, a pad electrode PE, and/or the like, may be on the upper portion of the interlayer insulation layer 115. The electrode layer E may be a source electrode, a drain electrode, a data line, and/or the like.

The electrode layer E, the second electrode CE2 of the storage capacitor Cst, and the pad electrode PE may include a conductive material (e.g., an electrically conductive material) including copper (Cu), titanium (Ti), molybdenum (Mo), aluminum (Al), a conductive metal oxide (e.g., an electrically conductive oxide), and/or the like, and may be formed as a multi-layer or single layer including the above materials. The conductive metal oxide may be an oxide of indium (In), tin (Sn), gallium (Ga), zinc (Zn), aluminum (Al), or any suitable combination thereof. The conductive metal oxide may be indium tin oxide (ITO), indium zinc oxide (IZO), zinc oxide (ZnO), indium oxide (In₂O₃), indium gallium oxide (IGO), aluminum zinc oxide (AZO), or a suitable combination thereof. In an embodiment, the electrode layer E, the second electrode CE2 of the storage capacitor Cst, and the pad electrode PE may be formed of a multi-layer structure of Ti/Cu/ITO.

The electrode layer E may be connected to the source area S or the drain area D of the semiconductor layer A through a contact hole. Furthermore, the bottom metal layer BML and the source area S or the drain area D of the semiconductor layer A may be connected through a contact hole formed in the buffer layer 111 and the interlayer insulation layer 115.

The second electrode CE2 of the storage capacitor Cst overlaps the first electrode CE1 with an interlayer insulation layer 115 therebetween, to thereby provide capacitance. In embodiments, the interlayer insulation layer 115 may function as a dielectric layer of the storage capacitor Cst.

The electrode layer E, the second electrode CE2 of the storage capacitor Cst and the pad electrode PE may be patterned concurrently (e.g., simultaneously).

The electrode layer E, the second electrode CE2 of the storage capacitor Cst and the pad electrode PE may be covered with an inorganic protective layer PVX. The inorganic protective layer PVX may be an inorganic insulation film including or consisting of an inorganic material. Silicon nitride, silicon oxide, silicon oxynitride, and/or the like may be used as inorganic materials. In embodiments, the inorganic protective layer PVX may be a single film or multi-layer film of silicon nitride (SiN_{X}) and silicon oxide (SiO_{X}). The inorganic protective layer PVX may be introduced to cover and protect some wirings on the interlayer insulation layer 115.

The inorganic protective layer PVX may include a contact hole CNT to connect a thin-film transistor (TFT) and a pixel electrode 310 and an opening (OP) to expose a pad portion PAD. As described in FIG. 1, a printed circuit board and/or driver IC chip may be attached to the pad portion PAD.

A planarization layer 117 provided to cover the electrode layer E and the second electrode CE2 of the storage capacitor Cst, and the planarization layer 117 may include a contact hole CNT to connect the thin-film transistor TFT and the pixel electrode 310.

The planarization layer 117 may be formed as a single layer or a multi-layer of a film including or consisting of an organic material and provide a flat upper surface. This planarization layer 117 may include a polymer such as benzocyclobutene (BCB), polyimide, hexamethyldisiloxane (HMDSO), polymethylmethacrylate (PMMA), polystyrene (PS), a phenol-based polymer, an acrylic-based polymer, an imide-based polymer, an aryl ether-based polymer, an amide-based polymer, a fluorine-based polymer, a p-xylene-based polymer, a vinyl alcohol-based polymer, or a suitable combination thereof.

In an embodiment, the planarization layer 117 may be provided to expose the pad portion PAD.

A light-emitting element 300 is on the planarization layer 117. The light-emitting element 300 includes a pixel electrode 310, an intermediate layer 320 including an emission layer, and a counter electrode 330.

The pixel electrode 310 may be a (semi) light-transmitting electrode or a reflective electrode. In some embodiments, the pixel electrode 310 may be provided with a reflective layer formed of Ag, Mg, Al, Pt, Pd, Au, Ni, Nd, Ir, Cr, or compounds thereof, and a transparent or semi-transparent electrode layer formed on the reflective layer. The transparent or semi-transparent electrode layer may include at least one or more selected from the group consisting of indium tin oxide (ITO), indium zinc oxide (IZO), zinc oxide (ZnO), indium oxide (In₂O₃), indium gallium oxide (IGO), and aluminum zinc oxide (AZO). In an embodiment, the pixel electrode 310 may be provided with a multi-layer structure of ITO/Ag/ITO.

A pixel definition film 119 may be on the planarization layer 117. The pixel definition film 119 covers an edge of the pixel electrode 310 and may have an opening to expose a portion of the pixel electrode 310. The pixel definition film 119 may serve to prevent or reduce an occurrence, likelihood, or degree of arc discharge, and/or the like, at the edge of the pixel electrode 310 by increasing the distance between the edge of the pixel electrode 310 and the counter electrode 330 on the upper portion of the pixel electrode 310.

The pixel definition film 119 may be formed by a method of spin coating, and/or the like, using one or more organic insulation materials (e.g., organic electrical insulation materials) selected from the group consisting of polyimide, polyamide, acrylic resin, benzocyclobutene, and phenolic resin.

The intermediate layer 320 is between the pixel electrode 310 and the counter electrode 330 within the opening formed by the pixel definition film 119 and may include an emission layer. The emission layer may include an organic material and/or an inorganic material including a fluorescent and/or phosphorescent material that emits red, green, blue, or white light. The organic material may be a low molecular weight organic material and/or a polymeric organic material, and the inorganic material may be a semiconductor quantum dot material.

Functional layers such as a hole transport layer (HTL), a hole injection layer (HIL), an electron transport layer (ETL), an electron injection layer (EIL), and/or the like, may be optionally below and above the emission layer.

The counter electrode 330 may be a light-transmitting electrode or a reflective electrode. In some embodiments, the counter electrode 330 may be a transparent or semi-transparent electrode and may be formed of a metal thin-film of a metal having a low work-function, including Li, Ca, Al, Ag, Mg, and/or compounds thereof, and/or multi-layer materials such as LiF/Ca (a stacked structure of LiF and Ca) or LiF/Al (a stacked structure of LiF and Al). In embodiments, a transparent conductive oxide (TCO) film such as ITO, IZO, ZnO or In₂O₃, and/or the like, may be further on the metal thin-film. The counter electrode 330 may be provided across the display area DA and may be on the intermediate layer 320 and the pixel definition film 119. The counter electrode 330 may be integrally provided in a plurality of light-emitting elements 300 and correspond to a plurality of pixel electrodes 310.

Because these light-emitting elements 300 may be easily damaged by moisture, oxygen, and/or the like, from the outside, a thin-film encapsulation layer may cover the organic light-emitting elements to protect them.

In the aforementioned display device 1, the etchant composition according to an embodiment may be used when forming the bottom metal layer BML, the gate electrode G, the electrode layer E, and the pad electrode PE.

Hereinafter, an etchant composition according to an embodiment will be described in more detail with reference to examples.

### EXAMPLE

### Preparation of Etchant Composition

### Examples 1 to 7 and Comparative Examples 1 to 10

Etchant compositions according to Examples 1 to 7 and Comparative Examples 1 to 10 were prepared with the compositions shown in Table 1 below. In Table 1, wt % refers to weight percent based on the total weight of the etchant composition. In Table 1, when the total weight of the etchant composition is 100 wt %, the remaining amount corresponds to deionized water.

In Table 1 below, APS is ammonium persulfate, ABF is ammonium bifluoride, HNO₃ is nitric acid, and ATZ is 5-aminotetrazole. In Table 1, the T/I ratio represents the weight ratio of ATZ to imidazole, and S/E hunting evaluates the degree of side etching by confirming the etched pattern using the etchant composition utilizing scanning electron microscope (SEM) photographs, which will be described in more detail herein.

TABLE 1

| | | | | | | Ammonium | Sulfamic | deionized | | |
|---|---|---|---|---|---|---|---|---|---|---|
| | APS | ABF | HNO₃ | ATZ | Imidazole | chloride | acid | water | T/I | S/E |
| | (wt %) | (wt %) | (wt %) | (wt %) | (wt %) | (wt %) | (wt %) | (wt %) | ratio | Hunting |
| Example 1 | 8 | 0.6 | 3 | 1.4 | 0.5 | 1.1 | 2 | Remaining | 2.8 | Good |
| | | | | | | | | amount | | |
| Example 2 | 11 | 0.5 | 3 | 1.4 | 0.6 | 1.1 | 2 | Remaining | 2.3 | Good |
| | | | | | | | | amount | | |
| Example 3 | 12 | 0.6 | 4 | 1.2 | 0.4 | 1.2 | 2.5 | Remaining | 3 | Good |
| | | | | | | | | amount | | |
| Example 4 | 10 | 0.3 | 3.5 | 1.3 | 0.5 | 1.3 | 2.3 | Remaining | 2.6 | Good |
| | | | | | | | | amount | | |
| Example 5 | 8 | 0.3 | 4 | 1.4 | 0.3 | 1.2 | 2 | Remaining | 4.7 | Good |
| | | | | | | | | amount | | |
| Example 6 | 9 | 0.4 | 4 | 1.2 | 0.5 | 1.1 | 2 | Remaining | 2.4 | Good |
| | | | | | | | | amount | | |
| Example 7 | 13 | 0.5 | 3.5 | 1.3 | 0.8 | 1.0 | 2.6 | Remaining | 1.6 | Good |
| | | | | | | | | amount | | |
| Comparative | 10 | 0.6 | 3 | 1.4 | 0 | 0.8 | 2 | Remaining | — | Defect |
| Example 1 | | | | | | | | amount | | |
| Comparative | 10 | 0.6 | 3 | 0 | 0.6 | 0.8 | 2 | Remaining | 0 | Defect |
| Example 2 | | | | | | | | amount | | |
| Comparative | 10 | 0.6 | 3 | 1.4 | 0.2 | 0.8 | 2 | Remaining | 7 | Defective |
| Example 3 | | | | | | | | amount | | |
| Comparative | 8 | 0.5 | 4 | 1.1 | 0.9 | 0.9 | 2.5 | Remaining | 1.2 | Defective |
| Example 4 | | | | | | | | amount | | |
| Comparative | 12 | 0.3 | 3.5 | 1.2 | 0.1 | 1.0 | 2.4 | Remaining | 12 | Defective |
| Example 5 | | | | | | | | amount | | |
| Comparative | 11 | 0.7 | 3 | 1.4 | 1.0 | 1.1 | 2 | Remaining | 1.4 | Defective |
| Example 6 | | | | | | | | amount | | |
| Comparative | 10 | 0.4 | 3.5 | 1.0 | 1.1 | 0.7 | 2.2 | Remaining | 0.9 | Defective |
| Example 7 | | | | | | | | amount | | |
| Comparative | 14 | 0.5 | 4 | 1.1 | 0.9 | 1.2 | 2 | Remaining | 1.2 | Defective |
| Example 8 | | | | | | | | amount | | |
| Comparative | 9 | 0.6 | 3 | 1.3 | 0.1 | 1.2 | 2 | Remaining | 13 | Defective |
| Example 9 | | | | | | | | amount | | |
| Comparative | 13 | 0.5 | 3.5 | 1.6 | 0.3 | 1.1 | 2.3 | Remaining | 5.3 | Defective |
| Example | | | | | | | | amount | | |
| 10 | | | | | | | | | | |

### Production of Test Substrate

A film of Ti (200 Å)/Cu (6000 Å) was deposited on a glass substrate, and a photoresist was patterned on it to produce an etching test substrate. The width of the photoresist pattern was 20 μm, and the spacing between patterns was 8 μm. A plurality of the above etching test substrates were produced so that each of the etchant compositions of Examples 1 to 7 and Comparative Examples 1 to 10 could be evaluated.

### Evaluation Example 1

For each of the etchant compositions of Examples 1 to 7 and Comparative Examples 1 to 10, an etching test was performed by sequentially etching a plurality of the produced etching test substrates. The etchant composition was placed in a spray etching method experiment equipment (model name: ETCHER (TFT), SEMES), the temperature was set to about 28° C., followed by etching of the etching test substrate. The over-etching time was from end point detection (EPD) to 100% over etch. The sprayed etchant composition was circulated and reused.

A cross-section of the etching test substrate etched with the etchant composition was observed using SEM to measure the degree of side etching S/E. FIG. 3 is a schematic diagram illustrating a method of measuring side etching. Referring to FIG. 3, “S/E” represents a distance between the bottom edge of the etched photoresist PR pattern and the bottom edge of the etched copper pattern Cu.

For each of the etchant compositions of Examples 1 to 7 and Comparative Examples 1 to 10, etching test substrates were sequentially etched one by one, and the concentration of Cu²⁺ in the etchant composition according to the number of etched substrates was confirmed using an inductively coupled plasma-mass spectrometry (ICP-MS) analyzer (7900 ICP-MS, produced by Agilent).

Cross-sectional SEM images of the Ti/Cu patterns were observed for the test substrates etched when the concentration of Cu²⁺ in the etchant composition was 0 ppm (the first etched test substrate) and when it was 500 ppm, respectively, and the degree of side etching was measured from these images. When the number of etched test substrates is small, the concentration of Cu²⁺ in the etchant composition from the etched copper pattern is small, and when the number of etched test substrates is large, the concentration of Cu²⁺ in the etchant composition from the etched copper pattern may accumulate and increase. If the difference in side etching S/E as the number of etched substrates is large, the process stability decreases.

An S/E hunting item in Table 1 is an item that evaluates the difference between the S/E value of the Ti/Cu pattern of the test substrate etched by the etchant composition of 0 ppm Cu²⁺ and the S/E value of the Ti/Cu pattern of the test substrate etched by the etchant composition of 500 ppm Cu²⁺. If (e.g., when) the difference in S/E value is about 0 μm to about 0.1 μm, process stability is evaluated as ‘good,’ but when it is more than 0.1 μm, process stability is evaluated as ‘defective.’ If the etchant composition is frequently replaced to ensure process stability, the process cost and process time increase.

Referring to Table 1, the S/E hunting of the Ti/Cu pattern of the test substrate etched with the etchant compositions of Examples 1 to 7 is good, as 0.1 μm or less, but the S/E hunting of the Ti/Cu pattern of the test substrate etched with the etchant compositions of Comparative Examples 1 to 10 is more than 0.1 μm, and is defective. While the present disclosure is not limited to any particular mechanism or theory, the above is believed to because, in the case of the etchant compositions of Examples 1 to 7, as etching progresses, the copper ions generated in the etchant compositions are effectively chelated, thereby reducing the contribution of the copper ions to side etching by being oxidized, whereas, in the case of the etchant compositions of Comparative Examples 1 to 10, the chelation of the copper ions is not effective, so as etching progresses, the copper ions are continuously oxidized and contribute to side etching.

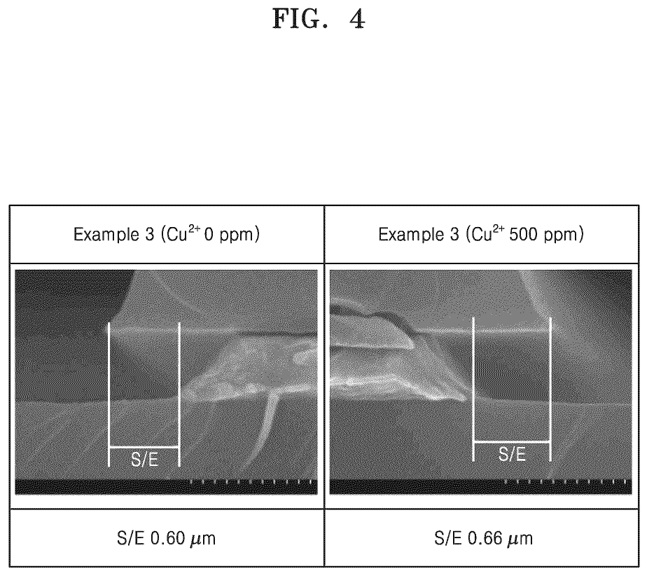

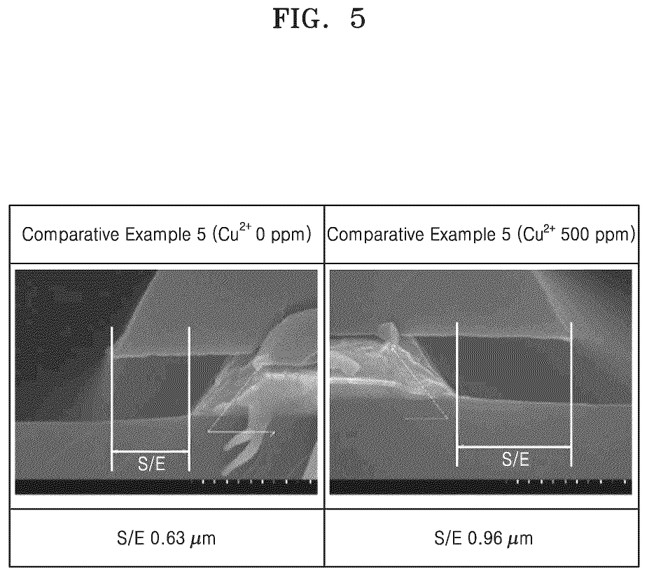

For example, the S/E values were measured and compared for the etching patterns using the etchant compositions of Example 3 and Comparative Example 5. FIG. 4 is a cross-sectional SEM image of a Ti/Cu pattern of a test substrate etched using the etchant composition of Example 3. The left image of FIG. 4 is an SEM image of an etched Ti/Cu pattern when the concentration of Cu²⁺ in the etchant composition was 0 ppm, and the right photo of FIG. 4 is an SEM image of an etched Ti/Cu pattern when the concentration of Cu²⁺ in the etchant composition was 500 ppm. FIG. 5 is a cross-sectional SEM image of a Ti/Cu pattern of a test substrate etched using the etchant composition of Comparative Example 5. The left image of FIG. 5 is an SEM image of an etched Ti/Cu pattern when the concentration of Cu²⁺ in the etchant composition was 0 ppm, and the right photo of FIG. 5 is an SEM image of an etched Ti/Cu pattern when the concentration of Cu²⁺ in the etchant composition was 500 ppm.

Referring to the SEM image of FIG. 4, in the case of Example 3, when the concentration of Cu²⁺ in the etchant composition increases from about 0 ppm to about 500 ppm, the side etching S/E degree increases by 10% from about 0.60 μm to about 0.66 μm. On the other hand, referring to the SEM image of FIG. 5, in the case of Comparative Example 5, when the concentration of Cu²⁺ in the etchant composition increases from about 0 ppm to about 500 ppm, the side etching S/E degree increases by 52% from about 0.63 μm to about 0.96 μm.

In the case of Comparative Example 5, the side etching becomes more severe as the number of etched test substrates increases, whereas in the case of Example 3, the increase in side etching does not appear to be significant even when the number of etched test substrates increases.

The etchant composition according to the embodiments enables etching of a metal multi-layer film while controlling the side etching profile.

Using the etchant composition according to the embodiments, a metal layer pattern in a semiconductor device may be reliably formed.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that various suitable changes in form and details may be made therein without departing from the spirit and scope of the present disclosure as defined by the following claims, and equivalents thereof.

What is claimed is:

1. An etchant composition, comprising:
about 3.0 wt % to about 15.0 wt % of ammonium persulfate;
about 0.1 wt % to about 5.0 wt % of an inorganic acid;
about 0.1 wt % to about 2.0 wt % of a fluorine-containing ammonium salt;
about 0.01 wt % to about 1.5 wt % of a chlorine-containing ammonium salt;
about 0.1 wt % to about 2.0 wt % of a 2-nitrogen cyclic compound;
about 0.1 wt % to about 2.0 wt % of a 4-nitrogen cyclic compound;
about 0.1 wt % to about 3.0 wt % of an aminosulfonic acid; and
a remainder of water, to bring the total weight of the etchant composition to be 100 wt %,
wherein a weight ratio of the 4-nitrogen cyclic compound to the 2-nitrogen cyclic compound is in a range of about 1.6 to about 5.0.

2. The etchant composition of claim 1,
wherein the inorganic acid comprises nitric acid (HNO₃), sulfuric acid (H₂SO₄), p-toluenesulfonic acid (CH₃C₆H₄SO₃), chloric acid (HClO₃), phosphoric acid (H₃PO₄), phosphorous acid (H₃PO₃) or a suitable combination thereof.

3. The etchant composition of claim 1,
wherein the inorganic acid is nitric acid.

4. The etchant composition of claim 1,
wherein the fluorine-containing ammonium salt comprises ammonium bifluoride.

5. The etchant composition of claim 1,
wherein the 2-nitrogen cyclic compound comprises imidazole, benzimidazole, pyrazole, indazole, pyridazine, pyrimidine, pyrazine, or any suitable combination thereof.

6. The etchant composition of claim 1,
wherein the 2-nitrogen cyclic compound is imidazole.

7. The etchant composition of claim 1,
wherein the aminosulfonic acid compound comprises sulfamic acid, taurine, cysteic acid, homocysteic acid, aminomethanesulfonic acid, 3-amino-1-propanesulfonic acid, or any suitable combination thereof.

8. The etchant composition of claim 1,
wherein the aminosulfonic acid is sulfamic acid.

9. The etchant composition of claim 1,
wherein the 4-nitrogen cyclic compound comprises 5-aminotetrazole, 5-methyltetrazole, 1-methyl-5-aminotetrazole, 1-ethyl-5-aminotetrazole, 5-mercapto-1-methyltetrazole, 5-methoxy-1H-tetrazole, 1H-tetrazole, or any suitable combination thereof.

10. The etchant composition of claim 9,
wherein the 4-nitrogen azole compound is 5-aminotetrazole.

11. A method of patterning a metal layer, comprising:
providing a substrate;
forming a metal layer on the substrate;
forming a photoresist pattern on the metal layer; and
etching the metal layer with the etchant composition of claim 1 to pattern the metal layer.

12. The method of claim 11,
wherein the metal layer is a multi-layer.

13. The method of claim 11,
wherein the metal layer comprises a metal, a metal oxide, a metal nitride, or a suitable combination thereof.

14. The method of claim 13,
wherein the metal comprises copper, titanium, a titanium alloy, or any suitable combination thereof,
and the titanium alloy comprises: titanium; and molybdenum (Mo), tantalum (Ta), chromium (Cr), nickel (Ni), neodymium (Nd), or any suitable combination thereof.

15. The method of claim 13,
wherein the metal oxide comprises an oxide of indium (In), tin (Sn), gallium (Ga), zinc (Zn), aluminum (Al) or any suitable combination thereof.

16. The method of claim 13,
wherein the metal oxide is indium tin oxide.

17. The method of claim 13,
wherein the metal nitride comprises titanium nitride, tantalum nitride, or a suitable combination thereof.

18. The method of claim 11,
wherein the metal layer comprises a first metal layer and a second metal layer,
the first metal layer comprises titanium, a titanium alloy, or a suitable combination thereof,
the titanium alloy comprises titanium and molybdenum (Mo), tantalum (Ta), chromium (Cr), nickel (Ni), neodymium (Nd), or any suitable combination thereof,
and the second metal layer comprises copper.

19. The method of claim 18,
wherein the metal layer further comprises a metal oxide layer on the second metal layer,
and the metal oxide layer comprises indium tin oxide.

20. A method of producing an electronic device, the method comprising:
providing a substrate;
forming a metal layer on the substrate;
forming a photoresist pattern on the metal layer; and
etching the metal layer with the etchant composition of claim 1 to form a metal layer pattern, wherein the display device comprises: a thin-film transistor comprising a semiconductor layer, a gate electrode, and a source/drain electrode;
and a light-emitting element electrically connected to the source/drain electrodes, wherein the metal layer pattern constitutes the gate electrode or the source/drain electrode.
